(19) United States
(12) Patent Application Publication
(10) Pub. No.: US 2007/0090350 A1
(43) Pub. Date: Apr. 26, 2007

(54) DISPLAY DEVICE AND METHOD FOR MANUFACTURING THE SAME

(75) Inventors: Sang-Pil LEE, Seoul (KR); Hoon KIM, Hwaseong-si (KR); Un-Cheol SUNG, Anyang-si (KR)

Correspondence Address: H.C. PARK & ASSOCIATES, PLC, 8500 LEESBURG PIKE, SUITE 7500, VIENNA, VA, 22182, US

(73) Assignee: SAMSUNG ELECTRONICS CO., LTD., Suwon-si (KR)

(21) Appl. No.: 11/551,849

(22) Filed: Oct. 23, 2006

(30) Foreign Application Priority Data
Oct. 24, 2005 (KR) 10-2005-0100396

(51) Int. Cl. H01L 29/08

(52) U.S. Cl. 257/40

(57) ABSTRACT

The present invention discloses a display device having a substrate, an organic material layer arranged on the substrate, a pixel electrode arranged on one surface of the organic material layer, a common electrode arranged on another surface of the organic material layer, and a light penetration layer through which light emitted from the organic material layer passes. The light penetration layer includes a curved pattern formed on at least one surface to refract light in a perpendicular direction to the substrate as it passes through the light penetration layer.

### CROSS REFERENCE TO RELATED APPLICATIONS

This application claims priority from and the benefit of Korean Patent Application No. 10-2005-0100396, filed on Oct. 24, 2005, which is hereby incorporated by reference for all purposes as if fully set forth herein.

### BACKGROUND OF THE INVENTION

1. Field of Invention

The present invention relates to a display device and a method for manufacturing the same, and more particularly, to a display device including a light penetration layer having a curved pattern formed on at least one surface thereof for refracting light emitted from an organic material layer to enhance a light efficiency, and a method for manufacturing the same.

2. Description of the Background

In a flat panel display device, the organic light emitting diode (hereinafter, referred to as “OLED”) has been widely used because the OLED requires a low driving voltage, is lightweight, has a thin shape, and provides a wide viewing angle and a high speed response. The OLED may be a passive matrix OLED or an active matrix OLED according to its driving method.

In the active matrix OLED, a thin film transistor is connected to each pixel region to control a light-emitting operation of each pixel region having an organic light-emitting layer. A pixel electrode is formed on each pixel region, and each pixel electrode is insulated electrically from an adjacent pixel electrode so that each pixel electrode is independently driven. A common electrode is formed on the organic light-emitting layer.

Light emitted from the organic light-emitting layer passes through various layers, each layer having a different refractive index, and radiates outwardly from the various layers. Because each layer has a different refractive index, the light scatters, lowering the brightness of the display device. Brighter light may be generated to compensate for the scattering, but generating brighter light may increase power consumption and accelerate deterioration of the light emitting element.

### SUMMARY OF THE INVENTION

This invention provides a display device that may reduce light scattering to improve the brightness of the display device.

This invention also provides a method for manufacturing a display device that may reduce light scattering to improve the brightness of the display device.

Additional features of the invention will be set forth in the description which follows, and in part will be apparent from the description, or may be learned by practice of the invention.

The foregoing and/or other aspects of the present invention can be achieved by providing a display device including a substrate, an organic material layer arranged on the substrate, a pixel electrode arranged on a first surface of the organic material layer, a common pixel electrode arranged on a second surface of the organic material layer, and a light penetration layer through which light emitted from the organic material layer passes. The light penetration layer includes a curved pattern arranged on at least one surface.

The foregoing and/or other aspects of the present invention can be achieved by providing a method for manufacturing a display device including the steps of forming a light penetration layer on a substrate, forming a pixel electrode on the light penetration layer, forming an organic material layer on the pixel electrode, and forming a common electrode on the organic material layer. The light penetration layer includes a curved pattern formed on at least one surface.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiments of the invention, and together with the description serve to explain the principles of the invention.

FIG. 1 illustrates a schematic of an equivalent circuit diagram of the display device according to the first exemplary embodiment of the present invention.

FIG. 2 illustrates a cross-sectional view of the display device according to the first exemplary embodiment of the present invention.

FIG. 3 illustrates a curved pattern of a light penetration layer according to the first exemplary embodiment of the present invention.

FIG. 4A, FIG. 4B, and FIG. 4C illustrate cross-sectional views for a method for manufacturing the display device according to the first exemplary embodiment of the present invention.

FIG. 5 illustrates a curved pattern of a light penetration layer according to a second exemplary embodiment of the present invention.

FIG. 6, FIG. 7 and FIG. 8 illustrate cross-sectional views of the display devices according to the third, fourth and fifth exemplary embodiments of the present invention, respectively.

### DETAILED DESCRIPTION OF THE ILLUSTRATIVE, NON-LIMITING EMBODIMENTS OF THE INVENTION

The invention is described more fully hereinafter with reference to the accompanying drawings, in which embodiments of the invention are shown. This invention may, however, be embodied in many different forms and should not be construed as limited to the embodiments set forth herein. Rather, these embodiments are provided so that this disclosure is thorough, and will fully convey the scope of the invention to those skilled in the art. In the drawings, the size and relative size of layers and regions may be exaggerated for clarity. Like reference numerals in the drawings denote like elements.

It will be understood that when an element such as a layer, film, region or substrate is referred to as being “on” or “connected to” another element or layer, it can be directly on or directly connected to the other element or layer, or intervening elements or layers may also be present. In contrast, when an element is referred to as being “directly on” or “directly connected to” another element or layer, there are no intervening elements or layers present.

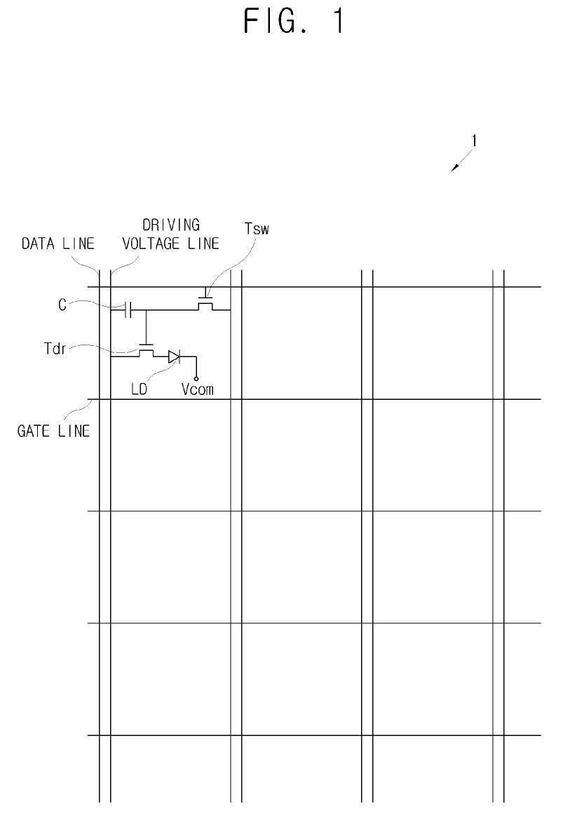

FIG. 1 illustrates a schematic of an equivalent circuit diagram of the display device according to the first exemplary embodiment of the present invention. Referring to FIG. 1, a display device 1 comprises a plurality of signal lines.

The signal lines include gate lines for transmitting a scan signal, data lines for transmitting a data signal and driving voltage lines for transmitting a driving voltage. The data lines and the driving voltage lines are disposed adjacent to and parallel to each other. The gate lines extend perpendicular to the data lines and the driving voltage lines.

Each pixel includes an organic light emitting element LD, a switching transistor Tsw, a driving transistor Tdr and a capacitor C.

The driving transistor Tdr has a control terminal, an input terminal and an output terminal. The control terminal is connected to the switching transistor Tsw, the input terminal is connected to the driving voltage line and the output terminal is connected to the organic light emitting element LD.

The organic light emitting element LD includes an anode connected to an output terminal of the driving transistor Tdr and a cathode connected to a common voltage terminal Vcom. The organic light emitting element LD emits light, whose magnitude varies according to an output current of the driving transistor Tdr to display an image. The magnitude of the output current of the driving transistor TDr varies according to a voltage applied to the control terminal and the input terminal.

The switching transistor Tsw has a control terminal, an input terminal and an output terminal. The control terminal is connected to the gate line, the input terminal is connected to the data line and the output terminal is connected to the control terminal of the driving transistor Tdr. The switching transistor Tsw transmits the data signal applied to the data line to the driving transistor Tdr in response to the scan signal applied to the gate line.

The capacitor C is coupled between the control terminal and the input terminal of the driving transistor Tdr. The capacitor C charges the data signal input to the control terminal of the driving transistor Tdr.

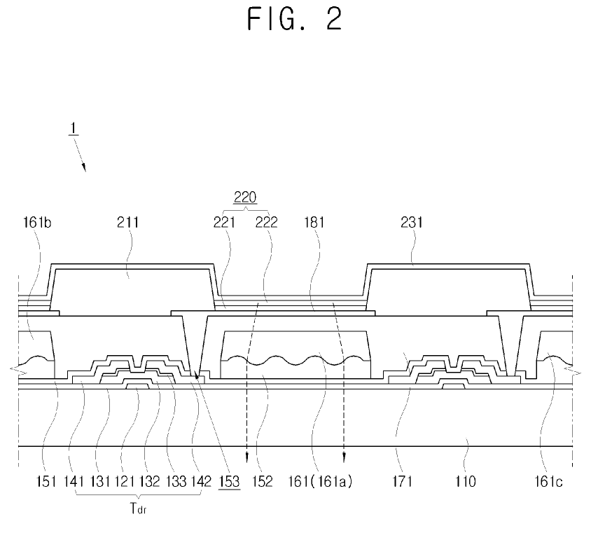

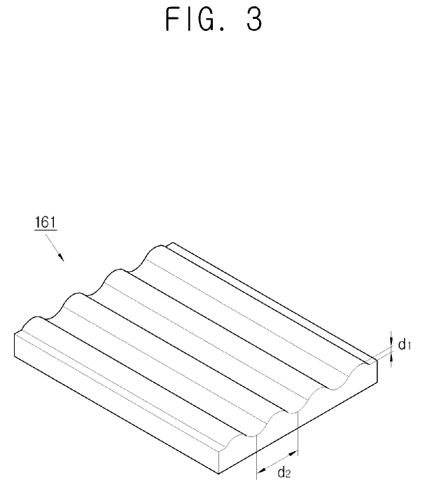

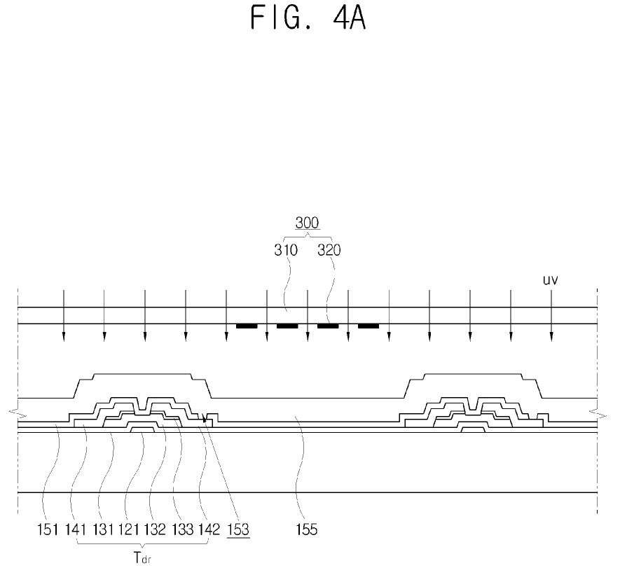

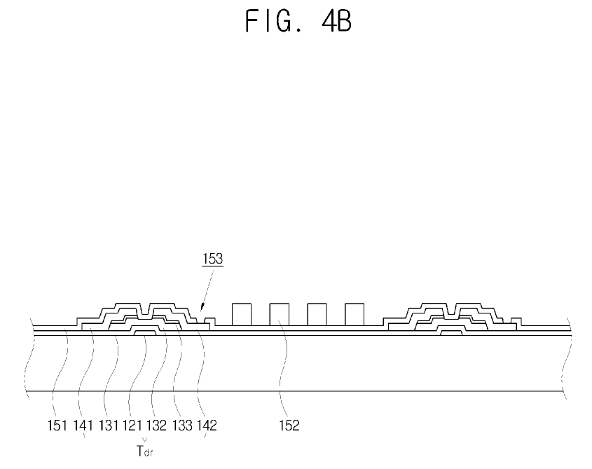

The display device according to the first exemplary embodiment is described in detail with reference to FIG. 2 and FIG. 3 as follows. FIG. 2 illustrates a cross-sectional view of the display device according to the first exemplary embodiment of the present invention and FIG. 3 illustrates a curved pattern of a light penetration layer according to the first exemplary embodiment of the present invention. In FIG. 2, only the driving transistor Tdr is shown.

A gate electrode 121 is arranged on a substrate 110, which may be made of an insulating material such as glass, quartz, ceramic or plastic, and the like. A gate insulating layer 131 made of silicon nitride (SiN_{X}) and the like is arranged on the substrate 110 and the gate electrode 121.

A semiconductor layer 132 made of amorphous silicon and an ohmic contact layer 133 made of a n⁺ hydrogenated amorphous silicon doped with a high concentration of a n-type impurity are arranged sequentially on the gate insulating layer 131 at a location where the gate electrode 121 is arranged. The ohmic contact layer 133 is divided into two portions, each portion of the ohmic contact layer 133 being arranged on either side of the gate electrode 121 with the gate electrode 121 being the center.

A source electrode 141 and a drain electrode 142 are arranged on the ohmic contact layer 133 and the gate insulating layer 131. The source electrode 141 and the drain electrode 142 are arranged on either side of the gate electrode 121 with the gate electrode 121 being the center.

A passivation layer 151 is arranged on the source electrode 141, the drain electrode 142, and a portion of the semiconductor layer 132 which is not covered with the source electrode 141 and the drain electrode 142. The passivation layer 151 may be formed from silicon nitride (SiNₓ). A portion of the passivation layer 151 corresponding to the drain electrode 142 is removed.

A first organic material member 152 is arranged on the passivation layer 151. The first organic material member 152 is arranged between adjacent thin film transistors Tdr, like an island. A curved pattern is formed on an upper side surface (that is, a surface facing toward an organic material layer 220) of the first organic material member 152. The first organic material member 152 may be formed from any one of benzocyclobutene (BCB), olefin, acrylic resin, polyimide, Teflon, cytop and perfluorocyclobutane (PFCB).

A color filter 161, which acts as a light penetration layer, is arranged on the first organic material member 152. The color filter 161 is also arranged between adjacent thin film transistors Tdr, like an island. A curved pattern is formed on a lower side surface (that is, a light-radiating surface facing toward the substrate 110) of the color filter 161, this curved pattern of the color filter 161 is engaged with the curved pattern formed on the first organic material member 152. The color filter 161 includes a red colored filter 161a, a green colored filter 161b, and a blue colored filter 161c, which are disposed in the curved pattern.

The curved pattern formed on the color filter 161 is described with reference to FIG. 3. FIG. 3 illustrates an inverted view of the color filter 161 of FIG. 2. The curved pattern of the color filter 161, which may include a sinusoidal pattern, includes amplitude of height d1, which may be about 1 μm to about 6 μm. The curved pattern of the color filter 161 further includes a width d2 between adjacent peaks or troughs, which may be about 1 μm to about 10 μm.

Although the first organic material member 152 may be arranged on the passivation layer 151 between adjacent thin film transistors Tdr, the first organic material member 152 may extend to an upper side of the thin film transistor Tdr. In this case, the curved pattern is formed on and across the upper side surface of the entire first organic material member 152 or may be formed on only a portion of the upper side surface of the first organic material member 152 corresponding to the location of the color filter 161.

A second organic material member 171 is arranged on the color filter 161 and the passivation layer 151 covering the thin film transistor Tdr. An upper side of the second organic material member 171 is generally flat and a portion of the second organic material member 171 corresponding to the location of the drain electrode 142 is removed. The second organic material member 171 may be formed from any one of benzocyclobutene (BCB), olefin, acrylic resin, polyimide, Teflon, cytop and perfluorocyclobutane (PFCB).

A pixel electrode 181 is arranged on the second organic material member 171. The pixel electrode 181 may be an anode for supplying holes to the organic material layer 220. The pixel electrode 181 may be formed from a transparent conductive material like indium tin oxide (ITO) or indium zinc oxide (IZO) and connected to the drain electrode 142 through a contact hole 153.

A wall 211 surrounding the pixel electrode 181 is arranged on the second organic material member 171. The wall 211 divides the pixel electrode 181 to define a pixel area. The wall 211 also prevents the source electrode 141 and the drain electrode 142 of the thin film transistor Tdr from short-circuiting with a common electrode 231. The wall 211 can be made from a photosensitive material such as acrylic resin, polyimide resin, and the like, having heat-resistant or solvent-resistant properties, or a non-organic material such as silicon oxide (SiO₂) and titanium oxide (TiO₂). Also, the wall 211 may be formed with a dual-layered structure including an organic material layer and a non-organic material layer.

The organic material layer 220 is arranged on a portion of the pixel electrode 181, which is not covered with the wall 211. The organic material layer 220 includes a hole injecting layer 221 and a light emitting layer 222.

The hole injecting layer 221 is formed from hole injecting material, such as poly (3,4-ethylenedioxythiophene; PEDOT) and polystyrene sulfonic acid (PSS). Such hole injecting material is mixed with water and then processed in an ink jet manner in an aqueous suspension state to form the hole injecting layer.

The light emitting layer 222 emits white light and may also be formed by the ink jet manner. Since the light emitting layer emits white light, the light emitting layers 222 of all the pixels may be formed from the same material.

The common electrode 231 is arranged on the wall 211 and the light emitting layer 222. The common electrode 231 may be a cathode for supplying electrons to the light emitting layer 222. The common electrode 231 may be made of an opaque material, such as aluminum or silver. The light emitted from the light emitting layer 222 radiates toward the substrate 110.

Holes transmitted from the pixel electrode 181 combine with electrons transmitted from the common electrode 231 in the light emitting layer 222 to form excitons, which cause the light emitting layer 222 to emit light.

The display device 1 as described above adopts a bottom emission orientation by which the light emitted from the light emitting layer 222 is radiated toward the substrate 110. The white light emitted from the light emitting layer 222 is converted into colored light as the white light passes through the color filter 161.

A function of the curved pattern formed on the lower side surface of the color filter 161 is described in detail as follows.

The white light emitted from the light emitting layer 222 passes sequentially through the pixel electrode 181, the second organic material member 171, the color filter 161, the first organic material member 152, the passivation layer 151, the gate insulating layer 131, and the substrate 110, and then radiates outwardly.

An incident angle of the white light emitted from the light emitting layer 222 and entering the pixel electrode 181 is not limited. The white light scatters as it passes through the various layers, each layer having a different refractive index. Consequently, a brightness of the white light decreases after passing through various layers. According to this exemplary embodiment, the color filter 161 converts the white light passing through the color filter 161 into colored light. Simultaneously, the curved pattern formed on the light-radiating surface of the color filter 161 refracts the colored light in a direction perpendicular to the substrate 110, and then radiates the colored light outwardly. As a result, light efficiency may be enhanced and a current applied to the light emitting layer 222 may be reduced, thereby reducing the power consumption of the display device.

In order to enhance a light refraction effect obtained by the curved pattern, the color filter 161 is manufactured from a material having a refractive index which differs from a material used to form the first organic material member 152. However, if it is desirable to prevent an excessive refraction of light emitted from the display device, the color filter 161 and the first organic material member 152 are formed from material providing a difference of about 0.1 to about 0.5 between the refractive indices of both materials.

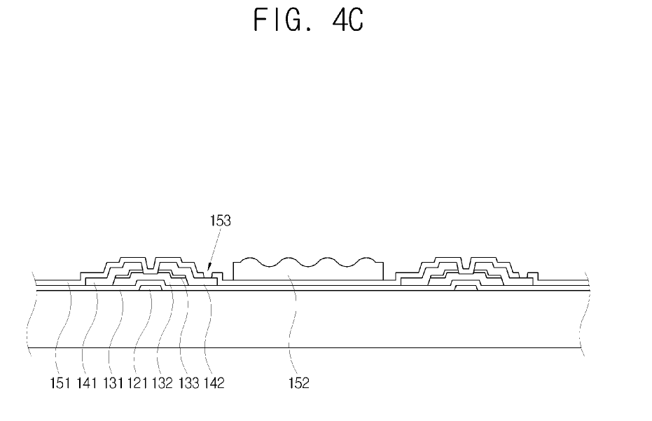

A method for manufacturing the display device according to the first exemplary embodiment of the present invention is described with reference to FIG. 4A, FIG. 4B, and FIG. 4C.

First, as shown in FIG. 4A, a first organic material member forming film 155 formed of a positive photosensitive material is arranged on the passivation layer 151 covering the thin film transistor Tdr. The thin film transistor Tdr may be formed by a known method, and the first organic material member forming film 155 may be formed by a conventional method, such as a spin coating method or a slit coating method. The first organic material member forming film 155 is exposed to the light through a mask 300, the mask 300 comprising a mask substrate 310 made from quartz and slits 320 formed from chrome and capable of blocking out ultraviolet light. Portions of the first organic material member forming film 155 which do not correspond to the location of the slits 320 are exposed to ultraviolet light.

FIG. 4b illustrates a cross-sectional view of the first organic material member forming film 155 after exposure to the ultraviolet light. Portions of the first organic material member forming film 155 not corresponding to the location of the slits 320 in the mask 300 are dissolved and removed by exposure to the ultraviolet light. Portions of the first organic material member forming film 155 not exposed to the ultraviolet light are not removed and form the first organic material members 152. The first organic material members 152 include a plurality of rectangular-shaped columns arranged in parallel at regular intervals.

FIG. 4c illustrates a cross-sectional view of the first organic material member 152 formed through a developing and reflow process, which includes heating the organic material member 152. The reflow process changes the rectangular-shaped column pattern of the first organic material member 152 into a sinusoidal shaped pattern.

Next, the color filter 161 is arranged on the first organic material member 152 where the curved pattern formed on the lower side surface of the color filter 161 corresponds to and engages the curved pattern formed on the upper side surface of the first organic material member 152. Subsequent processes are performed using conventional methods.

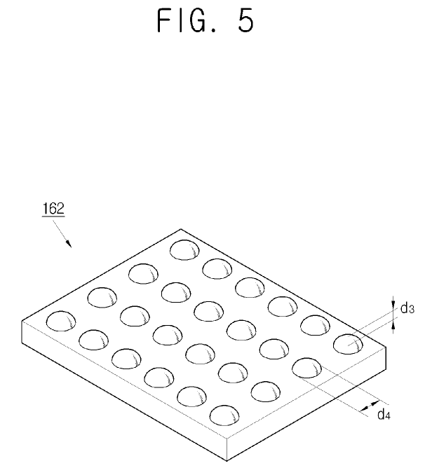

FIG. 5 illustrates a view for a curved pattern of the light penetration layer according to a second exemplary embodiment of the present invention.

A curved pattern of the color filter 162, which is the light penetration layer, has a pattern in which a plurality of hemispheres is disposed. A height d3 of each hemisphere may be about 2 μm to about 6 μm. A diameter d4 of each hemisphere can be about 4 μm to 10 μm.

The curved pattern of the color filter 162, which is the light penetration layer, is not limited to the shapes or patterns disclosed in the aforementioned embodiments described above. If the curved pattern of the color filter 162 may refract light passing through it in the direction perpendicular to the substrate 110, any shaped curved pattern of the color filter 162 may be adopted.

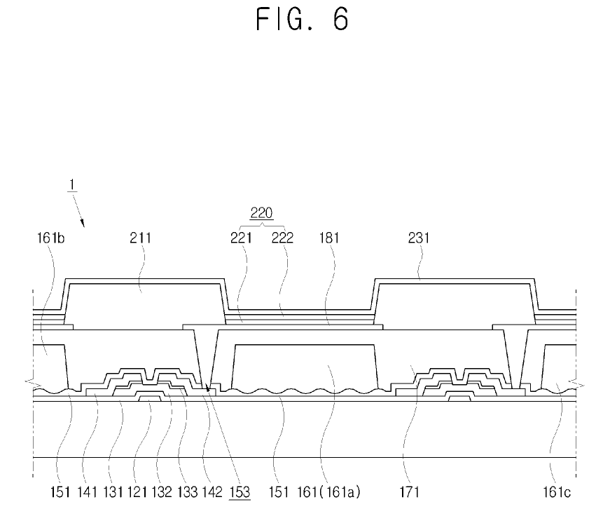

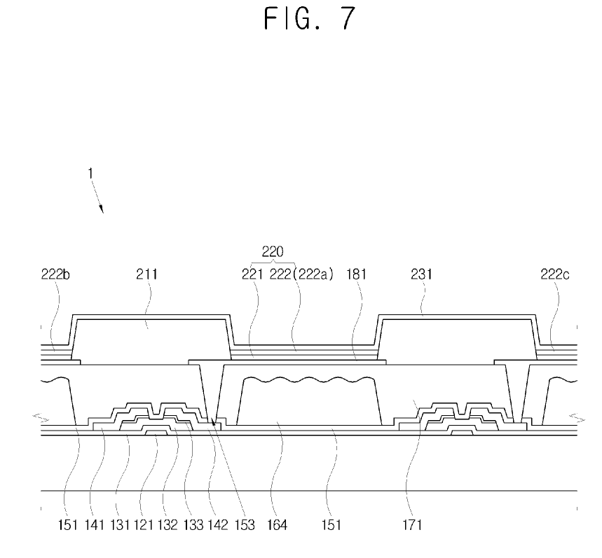

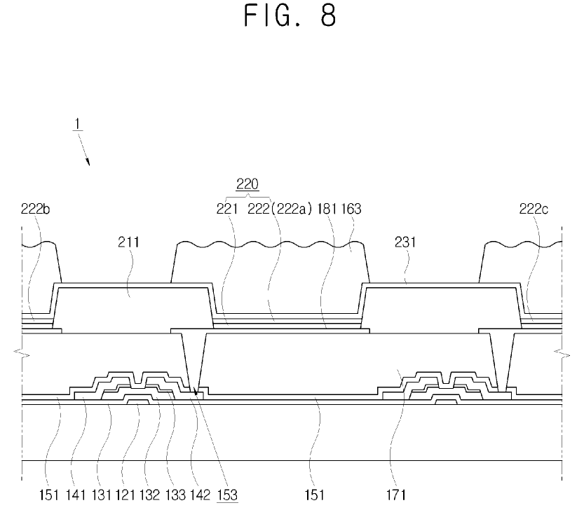

FIG. 6, FIG. 7, and FIG. 8 illustrate cross-sectional views of the display devices according to the third, fourth and fifth exemplary embodiments of the present invention, respectively.

According to the third exemplary embodiment, as shown in FIG. 6, the color filter 161 contacts the passivation layer 151 and the curved pattern is formed on an upper side surface of the passivation layer 151. Here, the passivation layer 151 may be formed from silicon nitride (SiN_{X}) and have a refractive index of about 1.7 and the color filter 161 may have a refractive index of about 1.6 to about 2.0. The white light emitted from the light emitting layer 222 passes sequentially through the pixel electrode 181, the second organic material member 171, the color filter 161, the passivation layer 151, the gate insulating layer 131, and the substrate 110, and then radiates outwardly. The color filter 161 converts the white light passing through the color filter 161 into colored light. Simultaneously, the curved pattern formed on the light-radiating surface of the color filter 161 refracts the colored light in a direction perpendicular to the substrate 110, and then radiates the colored light outwardly. As a result, light efficiency may be enhanced and a current applied to the light emitting layer 222 may be reduced, thereby reducing the power consumption of the display device.

According to the fourth exemplary embodiment, as shown in FIG. 7, a third organic material member 164, which is the light penetration layer, contacts the passivation layer 151 and the curved pattern is formed on a light entering surface of the organic material member 164. The light emitting layer 222 includes a red colored light emitting layer 222a, a green colored light emitting layer 222b, and a blue colored light emitting layer 222c, which are arranged in a prescribed pattern. Unlike the aforementioned embodiments, since each light emitting layer 222a, 222b, and 222c emits light whose color differs from the light emitted from the other layers, there is no need to form the color filter. The light emitting layer 222 can be formed by doping perylene-based dye, rhodamine-based dye, lubrene, pherylene, 9,10-diphenylanthracene, tetraphenylbutadiene, nile red, coumarin 6, quinacridone and the like to polyfluorene derivative, (poly)paraphenylenevinylene derivative, polyphenylene derivative, polyvinylcarbazole derivative, polythiophene derivative or polymer thereof.

The third organic material member 164 can be formed from any one of benzocyclobutene (BCB), olefin, acrylic resin, polyimide, Teflon, cytop, and perfluorocyclobutane (PFCB). The second organic material member 171 may be formed from a material having a refractive index which differs from that of a material used for forming the third organic material member 164.

Each colored light emitted from the light emitting layer 222 passes sequentially through the pixel electrode 181, the second organic material member 171, the third organic material member 164, the passivation layer 151, the gate insulating layer 131, and the substrate 110, and then radiates outwardly. Simultaneously, the curved pattern formed on the light-entering surface of the third organic material member 164 refracts the light in a direction perpendicular to the substrate 110, and then radiates the light outwardly. As a result, light efficiency may be enhanced and a current applied to the light emitting layer 222 may be reduced, thereby reducing the power consumption of the display device.

According to the fifth exemplary embodiment, as shown in FIG. 8, a fourth organic material member 163, which is the light penetration layer, is arranged on the common electrode 231 and has the curved pattern formed on a light-exiting surface of the fourth organic material member 163. The light emitting layer 222 includes a red colored light emitting layer 222a, a green colored light emitting layer 222b, and a blue colored light emitting layer 222c, which are disposed in a prescribed pattern. Since each light emitting layer 222a, 222b, and 222c emits light whose color differs from the light emitted from the other layers, the color filter is not formed.

The fourth organic material member 163 may be formed from any one of benzocyclobutene (BCB), olefin, acrylic resin, polyimide and fluoropolymer such as perfluorocyclobutane (PFCB). Although not shown in the drawing, a capping layer may be further arranged on the fourth organic material member 163. It is preferable that a material having a refractive index which differs from that of the material used for forming the fourth organic material member 163 is used for forming the capping layer.

According to the fifth exemplary embodiment, as shown in FIG. 8, the common electrode 231 is transparent since the light emitted from the light emitting layer 222 passes through the common electrode 231. The common electrode 231 may be formed from an alloy of magnesium and silver or an alloy of calcium and silver. Also, a thickness of the common electrode 231 may be 50 nm to 200 nm. If a thickness of the common electrode 231 is below 50 nm, a resistance may become excessively large thereby preventing smooth application of a common voltage to the display device. If a thickness of the common electrode 231 is above 200 nm, the common electrode 231 may become opaque. The common electrode 231 may be formed having a double-layered structure including an alloy layer and a transparent electrode layer.

Each colored light emitted from the light emitting layer 222 passes sequentially through the common electrode 231 and the fourth organic material member 163 and then radiates outwardly. The curved pattern formed on the light-exiting surface of the fourth organic material member 163 refracts light in a direction perpendicular to the substrate 110, which permits the light to be radiated outwardly. As a result, light efficiency may be enhanced and a current applied to the light emitting layer 222 may be reduced, thereby reducing the power consumption of the OLED.

Unlike the fifth exemplary embodiment, the light emitting layer 222 emits the white light and the fourth organic material member 163 may be the color filter which converts the white light to colored light.

According to the display device and the method for manufacturing the same of the present invention as described above, a light dispersion phenomenon in the display device is reduced, creating an improved brightness for the display device.

It will be apparent to those skill in the art that various modifications and variation can be made in the present invention without departing from the spirit or scope of the invention. Thus, it is intended that the present invention cover the modifications and variations of this invention provided they come within the scope of the appended claims and their equivalents.

What is claimed is:

1. A display device, comprising:
a substrate;
an organic material layer arranged on the substrate;
a pixel electrode arranged on a first surface of the organic material layer;
a common electrode arranged on a second surface of the organic material layer; and
a light penetration layer through which light emitted from the organic material layer passes, the light penetration layer comprising a curved pattern arranged on at least one surface thereof.

2. The display device of claim 1, wherein the light penetration layer is arranged between the substrate and the organic material layer.

3. The display device of claim 2, wherein the curved pattern is arranged on a surface of the light penetration layer facing toward the substrate.

4. The display device of claim 3, further comprising a silicon nitride layer in contact with the curved pattern.

5. The display device of claim 4, wherein the light penetration layer has a refractive index of about 1.6 to about 2.0.

6. The display device of claim 2, wherein the curved pattern is arranged on a surface of the light penetration layer facing toward the organic material layer.

7. The display device of claim 1, wherein the light emitted from the organic material layer passes through the common electrode and then enters the light penetration layer.

8. The display device of claim 7, wherein the curved pattern is arranged on a light-exiting surface of the light penetration layer.

9. The display device of claim 1, further comprising an organic material member in contact with the curved pattern.

10. The display device of claim 9, wherein the organic material member comprises a surface on which a curved pattern is arranged, and the curved pattern of the organic material member is engaged with the curved pattern of the light penetration layer.

11. The display device of claim 10, wherein the light penetration layer is arranged to correspond to the organic material member.

12. The display device of claim 1, wherein the light penetration layer is a color filter.

13. The display device of claim 12, wherein the organic material layer emits white light.

14. The display device of claim 1, wherein the light penetration layer is a silicon nitride layer.

15. The display device of claim 1, wherein the curved pattern has a sinusoidal shape.

16. The display device of claim 15, wherein a distance between peaks or troughs of the sinusoidal shape is about 1 μm to about 10 μm.

17. The display device of claim 15, wherein an amplitude of the sinusoidal shape is about 1 μm to about 6 μm.

18. The display device of claim 1, wherein the curved pattern has a shape in which a plurality of hemispheres are dotted.

19. A method for manufacturing a display device, comprising:
forming a light penetration layer on a substrate;
forming a pixel electrode on the light penetration layer;
forming an organic material layer on the pixel electrode; and
forming a common electrode on the organic material layer,
wherein the light penetration layer comprises a first curved pattern formed on at least one surface thereof.

20. The method of claim 19, wherein the light penetration layer comprises a photosensitive material and the first curved pattern is formed using a slit mask.

21. The method of claim 19, further comprising:
forming an organic material member on the substrate,
wherein the organic material member comprises a second curved pattern formed thereon;
wherein the light penetration layer is formed on the organic material member; and
wherein the second curved pattern of the organic material member is engaged with the first curved pattern.
